(19) United States
(12) Patent Application Publication
(10) Pub. No.: US 2025/0280658 A1
(43) Pub. Date: Sep. 4, 2025

(54) LIGHT EMITTING DISPLAY APPARATUS

(71) Applicant: LG DISPLAY CO., LTD., Seoul (KR)

(72) Inventor: KyungEon LEE, Paju-si (KR)

(73) Assignee: LG DISPLAY CO., LTD., Seoul (KR)

(21) Appl. No.: 18/899,650

(22) Filed: Sep. 27, 2024

(30) Foreign Application Priority Data
Feb. 29, 2024 (KR) 10-2024-0030280

(51) Int. Cl. H10K 59/121; H10K 59/131

(52) U.S. Cl. CPC H10K 59/1213; H10K 59/131

(57) ABSTRACT

A light emitting display apparatus includes a light emitting element including a pixel electrode, an emission layer, and a common electrode, and a pixel circuit connected to the pixel electrode of the light emitting element and configured to include at least one thin film transistor, wherein the pixel electrode is divided into a first pixel divided electrode and a second pixel divided electrode, and at least a portion of the at least one thin film transistor is configured as a dual transistor connected to each of the first pixel divided electrode and the second pixel divided electrode.

### CROSS-REFERENCE TO RELATED APPLICATION

This application claims the priority of Korean Patent Application No. 10-2024-0030280 filed on Feb. 29, 2024, which is hereby incorporated by reference in its entirety.

### BACKGROUND

### Field of the Disclosure

The present disclosure relates to a light emitting display apparatus.

### Description of the Background

With the development of information society, the demand for a display apparatus for displaying an image is increasing in various forms. Accordingly, display apparatuses such as a liquid crystal display (LCD) apparatus, an organic light emitting display (OLED) apparatus, a micro light emitting diode LED display apparatus, a quantum dot display (QD) apparatus, and the like are used.

Among the display apparatuses, the organic light emitting display apparatus is a self-luminous type. In the organic light emitting display apparatus, hole and electron are injected into an emission layer from an anode electrode for hole injection and a cathode electrode for electron injection, and the injected hole and electron are bonded to each other. Herein, when the bonded hole and electron exciton fall from the excited state to the ground state, the organic light emitting display apparatus may emit light and display an image.

The organic light emitting display apparatus has a problem in that dark spots may occur due to the generation of foreign substances between the anode electrode and the cathode electrode in a process of forming the cathode electrode of light emitting element through a sputtering process.

### SUMMARY

The present disclosure has been made in view of the above described problems, and the present disclosure is to provide a light emitting display apparatus having a repair structure for a short defect between an anode electrode and a cathode electrode.

The present disclosure is also to provide a light emitting display apparatus capable of automatically detecting a semi-dark repair target by independently driving divided subpixels through the use of dual transistor having a mirror structure.

The present disclosure is not limited to the previously mentioned, but other features not described herein will be clearly understood by those skilled in the art from descriptions below.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a light emitting display apparatus includes a light emitting element including a pixel electrode, an emission layer, and a common electrode, and a pixel circuit connected to the pixel electrode of the light emitting element and configured to include at least one thin film transistor, wherein the pixel electrode is divided into a first pixel divided electrode and a second pixel divided electrode, and at least a portion of the at least one thin film transistor is configured as a dual transistor connected to each of the first pixel divided electrode and the second pixel divided electrode.

To achieve these and other advantages and in accordance with the present disclosure, as embodied and broadly described, a light emitting display apparatus includes a light emitting element including a pixel electrode, an emission layer, and a common electrode, and a pixel circuit connected to the pixel electrode of the light emitting element and configured to include at least one thin film transistor, the pixel electrode may be divided into a first pixel divided electrode and a second pixel divided electrode, the light emitting element may include a first divided light emitting element and a second divided light emitting element corresponding to the first pixel divided electrode and the second pixel divided electrode, respectively, and at least one thin film transistor may comprise a first driving transistor configured to drive the first divided light emitting element, and a second driving transistor configured to drive the second divided light emitting element.

According to one or more aspects of the present disclosure, it is possible to provide the light emitting display apparatus having the repair structure for the short defect between the anode electrode and the cathode electrode.

According to one or more aspects of the present disclosure, it is possible to provide the light emitting display apparatus capable of automatically detecting the semi-dark repair target by independently driving divided subpixels through the use of dual transistor having the mirror structure.

The light emitting display apparatus according to one or more aspects of the present disclosure may improve the production yield by reducing the tack time of repair process through an accurate detection of the semi-dark repair target and improving the reliability of manufacturing process, whereby it is possible to implement Environment/Social/Governance (ESG) by reducing the generation of greenhouse gas that may occur due to the manufacturing process.

The effects of the present disclosure are not limited to the aforesaid, but other effects not described herein will be clearly understood by those skilled in the art from descriptions below.

The details of the present disclosure described in technical problem, technical solution, and advantageous effects do not specify essential features of claims, and thus, the scope of claims is not limited by the details described in detailed description of the disclosure.

### BRIEF DESCRIPTION OF THE DRAWINGS

The accompanying drawings, which are included to provide a further understanding of the disclosure and are incorporated in and constitute a part of the present disclosure, illustrate aspects of the disclosure and together with the description serve to explain principles of the disclosure.

In the drawings:

FIG. 1 illustrates a light emitting display apparatus according to an aspect of the present disclosure;

FIG. 2 is a block diagram illustrating a light emitting display apparatus according to an aspect of the present disclosure;

FIG. 3 is a circuit diagram illustrating a subpixel of a light emitting display apparatus according to an aspect of the present disclosure;

FIG. 4 illustrates a pixel of a light emitting display apparatus according to another aspect of the present disclosure;

FIG. 5 illustrates area A shown in FIG. 4 according to another aspect of the present disclosure;

FIG. 6 illustrates an area B shown in FIG. 5 according to another aspect of the present disclosure;

FIG. 7 is a cross-sectional view along line I-I′ of FIG. 6 according to another aspect of the present disclosure;

FIG. 8 is a cross-sectional view along line II-II′ of FIG. 6 according to another aspect of the present disclosure;

FIG. 9 is a cross-sectional view along line III-III′ of FIG. 6 according to another aspect of the present disclosure;

FIG. 10 is a circuit diagram illustrating a subpixel of a light emitting display apparatus according to another aspect of the present disclosure; and

FIGS. 11 to 16 illustrate a method of forming a subpixel of a light emitting display apparatus according to another aspect of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through the aspects described with reference to the accompanying drawings. The present disclosure may, however, be embodied in different forms and should not be construed as limited to the aspects set forth herein. Rather, these aspects are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used to describe example aspects, and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various aspects of the present disclosure may be partially or entirety coupled to or combined with each other, may be technically associated with each other, and may be variously inter-operated, linked or driven together. The aspects of the present disclosure may be implemented or carried out independently of each other, or may be implemented or carried out together in a co-dependent or related relationship. In one or more aspects, the components of each apparatus according to various aspects of the present disclosure are operatively coupled and configured.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

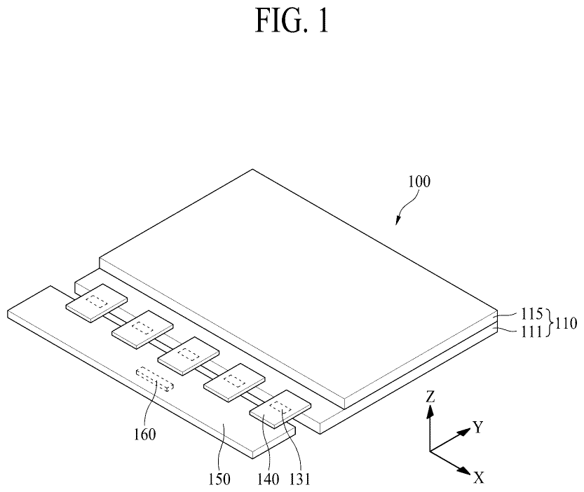

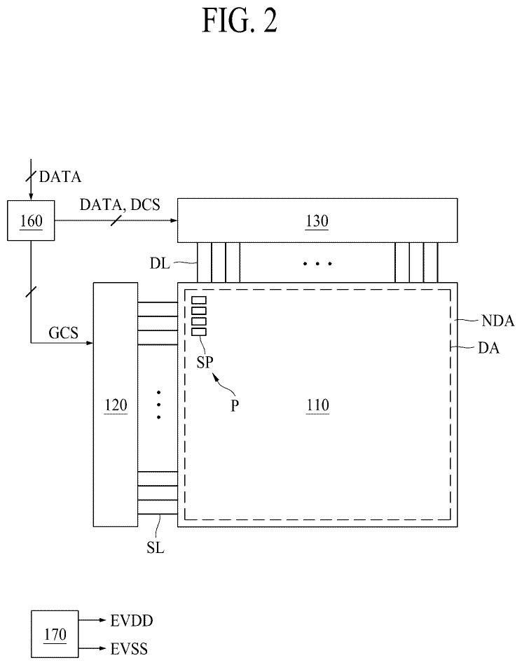

FIG. 1 illustrates a light emitting display apparatus according to an aspect of the present disclosure. FIG. 2 is a block diagram illustrating a light emitting display apparatus according to an aspect of the present disclosure.

A light emitting display apparatus 100 according to an aspect of the present disclosure is implemented as an organic light emitting display apparatus, but may also be implemented as a liquid crystal display apparatus, a quantum dot lighting emitting diode display apparatus, or an electrophoretic display apparatus.

Referring to FIGS. 1 and 2, the light emitting display apparatus 100 according to an aspect of the present disclosure may include a display panel 110, a scan driver 120 embedded in the display panel 110, a data driver 130 connected to the display panel 110, a timing controller 160 controlling the scan driver 120 and the data driver 130, and a power circuit 170.

The display panel 110 may include a substrate 111 and an opposite substrate 115. The opposing substrate 115 may be an encapsulation substrate. The substrate 111 may include a plastic film or a glass substrate, but aspects of the present disclosure are not limited thereto. For example, the substrate 111 may be formed of a semiconductor material such as a silicon wafer. The opposite substrate 115 may be a plastic film, a glass substrate, or an encapsulation film (or protection film).

The display panel 110 includes a display area DA and a non-display area NDA surrounding the display area DA. The display panel 110 includes pixels P provided in the display area DA to display an image. Each of the pixels P may include a plurality of subpixels SP. The structure of the subpixel SP may be variously changed according to the type of the light emitting display apparatus 100. For example, the subpixels SP may be formed in a top emission type, a bottom emission type, or a dual emission type according to the structure. The subpixels SP indicate a unit capable of forming a color filter of a specific type or capable of emitting a color of itself without forming a color filter. For example, the subpixels SP may include a red subpixel, a green subpixel, and a blue subpixel. Alternatively, the subpixels SP may include a red subpixel, a blue subpixel, a white subpixel, and a green subpixel. The subpixels SP may have one or more other light-emitting areas according to light-emitting characteristics. For example, the plurality of subpixels SP may be arranged in a quad type or a stripe type, but aspects of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may include data lines DL and scan lines SL (or gate line) connected to the subpixels SP. The data lines DL may be arranged to cross the scan lines SL. Each of the plurality of data lines DL may be configured to extend in a first direction. Each of the plurality of scan lines SL may be configured to extend in a second direction different from the first direction. Each of the subpixels SP of the display panel 110 may be connected to any one of the data lines DL and any one of the scan lines SL. The data lines DL may supply a data voltage supplied from the data driver 130 to each of the subpixels SP. The scan lines SL may supply a scan signal supplied from the scan driver 120 to each of the subpixels SP.

Each of the subpixels SP is turned-on by the scan signal. When the data voltage of the data line DL is supplied to a gate electrode of a driving transistor, a light emitting element may emit light according to a drain-to-source current of the driving transistor. The scan driver 120 may receive a scan control signal GCS from the timing controller 160. The scan driver 120 may supply the scan signals or emission control signal to the scan lines SL by using the scan control signal GCS.

The scan driver 120 may be configured in a gate driver in panel GIP manner in the non-display area NDA outside one side or both sides of the display area DA. Alternatively, the scan driver 120 may be manufactured as a driving chip, mounted on a flexible film, and attached to the non-display area NDA outside one side or both sides of the display area DA in a tape automated bonding TAB manner.

The data driver 130 may receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The data driver 130 may include a plurality of data drive ICs 131 as shown in FIG. 1. Each of the plurality of data drive ICs 131 may be mounted on the flexible film 140 by chip on film COF, chip on plastic COP, Flexible Printed Circuit FPC, or Flexible Flat Cable FFC. The flexible film 140 is attached on pads provided in the non-display area NDA of the display panel 110 by using an anisotropic conducting film, whereby the plurality of data drive ICs 131 may be connected to the pads.

The circuit board 150 may be attached to the flexible films 140. A plurality of circuits implemented as driving chips may be mounted on the circuit board 150. For example, the timing controller 160 may be mounted on the circuit board 150. The circuit board 150 may be a printed circuit board or a flexible printed circuit board.

The timing controller 160 receives digital video data DATA and timing signals from a host system. The timing signals may include a vertical synchronization signal, a horizontal synchronization signal, a data enable signal, a dot clock, and the like. The vertical synchronization signal is a signal defining one frame period. The horizontal synchronization signal is a signal defining one horizontal period required for supplying the data voltages to the pixels of one horizontal line of the display panel 110. The data enable signal defines a period in which valid data is input. The dot clock is a signal repeated at a predetermined short period.

The timing controller 160 may generate the data control signal DCS for controlling an operation timing of the data driver 130 and the scan control signal GCS for controlling an operation timing of the scan driver 120 based on the timing signals. The timing controller 160 may output the scan control signal GCS to the scan driver 120 and output the digital video data DATA and data control signal DCS to the data driver 130.

The power circuit 170 may generate and supply a plurality of driving voltages required for an operation of all circuit configurations of the display apparatus 100 by using an input voltage. The power circuit 170 may generate a first power supply voltage EVDD (or pixel power voltage), a second power supply voltage EVSS (or common power voltage) and an initialization voltage Vref (or reference voltage) and supply the generated voltages to the display panel 110. The power circuit 170 may generate and supply various driving voltages required for operations of the gate driver 120, the data driver 130, and the timing controller 160.

The power circuit 170 according to an aspect of the present disclosure may divide the initialization voltage Vref into a first initialization voltage (or normal driving voltage) and a second initialization voltage (or repair detecting voltage) and may generate the first initialization voltage and the second initialization voltage. For example, the first initialization voltage and the second initialization voltage may have different voltage levels. For example, the first initialization voltage may be a low potential voltage for initializing each subpixel SP during a normal driving period of the display panel 110, and the second initialization voltage may be a high potential voltage for detecting a semi-dark repair target of each subpixel SP during a repair detection period of the display panel 110, but aspects of the present disclosure are not limited thereto.

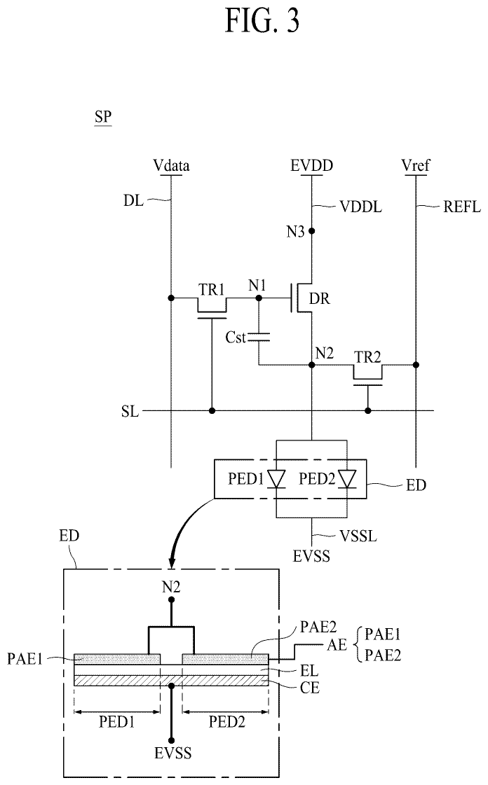

FIG. 3 is a circuit diagram illustrating a subpixel of a light emitting display apparatus according to an aspect of the present disclosure.

Referring to FIG. 3, each of pixels includes a plurality of subpixels SP constituting a unit pixel. In each of the plurality of subpixels SP, there are a pixel circuit having 3T (Transistor) 1C (Capacitor) including a driving transistor DR, a first switching transistor TR1, a second switching transistor TR2 and a storage capacitor Cst, and a light emitting element ED, but not limited thereto. Each subpixel SP may further include a compensation circuit. In this case, the subpixel SP may have various structures such as 4T2C, 5T2C, 6TIC, 6T2C, 7T1C, and 7T2C.

At least one thin film transistor DR, TR1 and TR2 of each subpixel SP may include a gate electrode, a source electrode, and a drain electrode. Since the source electrode and the drain electrode may be changed according to a voltage and a current direction applied to the gate electrode without being fixed, any one of the source electrode and the drain electrode may be represented as a first electrode, and the other may be represented as a second electrode. The at least one transistor DTR, TR1, and TR2 may use at least one of polysilicon semiconductor, amorphous silicon semiconductor, and oxide semiconductor. The transistors DTR, TR1, and TR2 may be P-type or N-type, or P-type and N-type may be interchangeably used.

The driving transistor DR may be configured as a transistor for driving the light emitting element ED, and the driving transistor DR includes a first node N1 to which a data voltage Vdata is applied, a second node N2 connected to a first electrode AE (pixel electrode or anode electrode) of the light emitting element ED, and a third node N3 connected to a pixel power line VDDL (or first power line) and supplied with a first power supply voltage EVDD (or pixel power voltage). For example, the first node N1 may be a gate node of the driving transistor DR, the second node N2 may be a source or drain node of the driving transistor DR, and the third node N3 may be a source or drain node of the driving transistor DR. For example, the second node N2 may be a source node, and the third node N3 may be a drain node, but aspects of the present disclosure are not limited thereto.

The first switching transistor TR1 may serve to supply the data voltage Vdata supplied from the data line DL to the driving transistor DT. The first switching transistor TR1 may switch an electrical connection between the data line DL and the first node N1. For example, the first switching transistor TR1 may be turned-on in response to the scan signal Scan applied through a scan line SL (or gate line). When the first switching transistor TR1 is turned-on, the data voltage Vdata applied through the data line DL may be transferred to the first node N1 of the driving transistor DR.

The second switching transistor TR2 may serve to supply a reference voltage Vref supplied from a reference line REFL to the driving transistor DR. The second switching transistor TR2 may switch an electrical connection between the reference line REFL and the second node N2. For example, the second switching transistor TR2 may be turned-on in response to the scan signal Scan applied through the scan line SL (or gate line). When the second switching transistor TR2 is turned-on, the reference voltage Vref applied through the reference line REFL may be transferred to the second node N2 of the driving transistor DR.

The storage capacitor Cst maintains the data voltage Vdata supplied to the driving transistor DR for one frame. The storage capacitor Cst may be connected between the first node N1 and the second node N2 of the driving transistor DR. For example, the storage capacitor Cst may store the voltage corresponding to the data voltage Vdata transferred through the first switching transistor TR1 and may turn on the driving transistor DR with the stored voltage.

The light emitting element ED may include the first electrode AE (pixel electrode or anode electrode) connected to the driving transistor, the second electrode CE (common electrode or cathode electrode) receiving a second power voltage EVSS (or common power voltage) from a common power line VSSL (or second power line), and an emission layer (or organic light emitting layer) between the first electrode AE and the second electrode CE. The first electrode AE may be an independent electrode for each light emitting element, but the second electrode CE may be a common electrode shared by the entire light emitting elements. When a driving current is supplied from the driving transistor DR, electrons from the second electrode CE are injected into the emission layer EL, and holes from the first electrode AE are injected into the emission layer EL, whereby fluorescent or phosphorescent materials emit through recombination of electrons and holes in the emission layer EL, thereby generating light of brightness proportional to a current value of the driving current.

The first electrode AE of the light emitting element ED may be connected to the second node N2 of the driving transistor DR, and the second electrode CE of the light emitting element ED may be connected to the common power line VSSL. The light emitting element ED may emit light in response to the driving current generated by the driving transistor DR.

The light emitting element ED according to an aspect of the present disclosure may comprise a first partial light emitting element PED1 and a second partial light emitting element PED2. The first partial light emitting element PED1 and the second partial light emitting element PED2 may be connected in common to the second node N2 of the driving transistor DR. The first electrode AE of the light emitting element ED may be divided into a first divided electrode PAE1 (or first pixel divided electrode) and a second divided electrode PAE2 (or second pixel divided electrode) spaced apart from each other. The second electrode CE of the light emitting element ED may be connected in common to the first divided electrode PAE1 and the second divided electrode PAE2. The second electrode CE receives the second power voltage EVSS from the common power line VSSL and applies the second power voltage EVSS to the first divided electrode PAE1 and the second divided electrode PAE2.

The first partial light emitting element PED1 may include the first divided electrode PAE1, the emission layer EL, and the second electrode CE. In addition, the second partial light emitting element PED2 may include the second divided electrode PAE2, the emission layer EL, and the second electrode CE. According to an aspect of the present disclosure, the light emitting element ED of each subpixel SP may include the first partial light emitting element PED1 and the second partial light emitting element PED2 by the first electrode AE divided into the first divided electrode PAE1 and the second divided electrode PAE2.

The light emitting element ED of each subpixel SP according to an aspect of the present disclosure is configured to be divided into the first partial light emitting element PED1 and the second partial light emitting element PED2. When a short occurs due to foreign substances in any one of the first partial light emitting element PED1 and the second partial light emitting element PED2 during a panel manufacturing process or after completion of panel production, a repair process may be carried out by darkening only the partial light emitting element with the short, and normally operating the remaining partial light emitting element.

The repair process according to an aspect of the present disclosure may include an aging repair process and a semi-dark repair process for removing an anode-cathode short AC short during the repair process after the panel manufacturing process or after shipping of panel product. For example, the aging repair process may remove the anode-cathode short with Joule Heating that generates heat from an anode-cathode short portion by applying a reverse bias voltage between the second electrode CE and the second node N2 of the driving transistor DT.

The semi-dark repair process checks the anode-cathode short portion, which is not removed by the aging repair process, as naked eyes (or a microscope) of a worker and carries out a cutting process by applying laser or physical force to the divided electrode of the partial light emitting element with the anode-cathode short of the first partial light emitting element PED1 and the second partial light emitting element PED2 of the light emitting element ED, whereby the half (½) of the light emitting element ED may be darkened, and the remaining half (½) of the light emitting element ED may be normally operated. However, in the light emitting display apparatus according to an aspect of the present disclosure, since a worker observes foreign substances with naked eye in the semi-dark repair process and proceeds with the repair process, a tact time is long. Also, when foreign matters are not seen, a repair success rate is lowered. In addition, another processing anode-cathode short may occur even after the semi-dark repair process is performed so that it is difficult to manage the yield of the light emitting display apparatus. Accordingly, the inventors of the present disclosure have invented a light emitting display apparatus having a new structure, which is capable of automatically detecting a semi-dark repair target for a semi-dark repair process and accurately detecting the semi-dark repair target, through various studies.

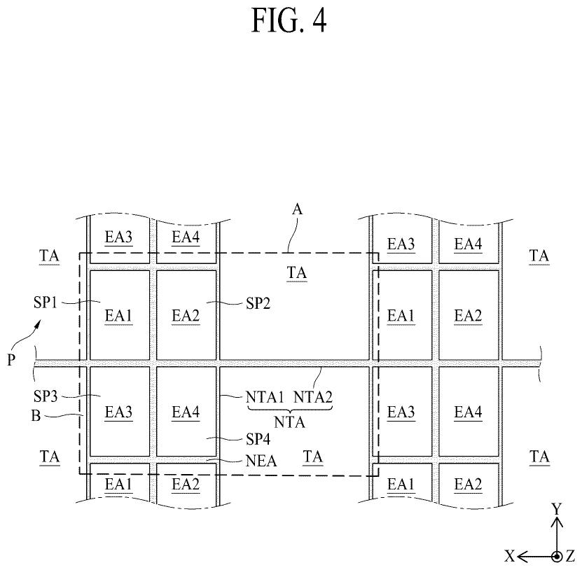

Hereinafter, a light emitting display apparatus according to an aspect of the present disclosure capable of automatically detecting a semi-dark repair target in a semi-dark repair process and accurately detecting the semi-dark repair target will be described in more detail with reference to FIGS. 4 to 16.

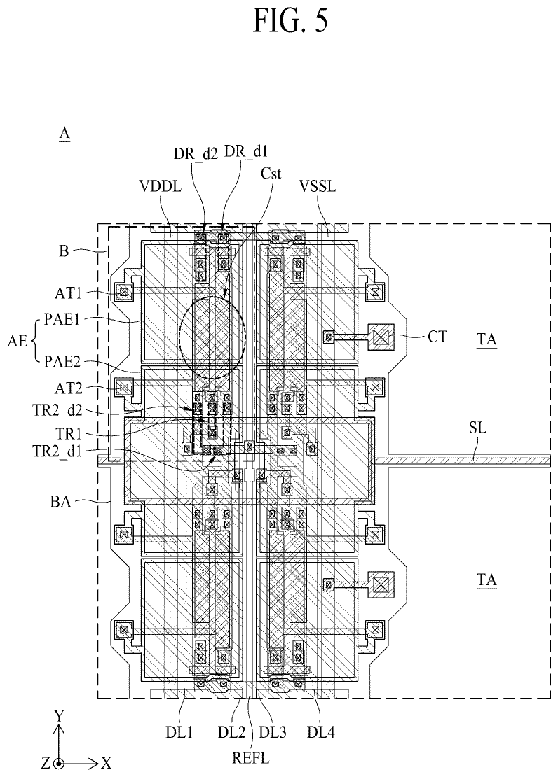

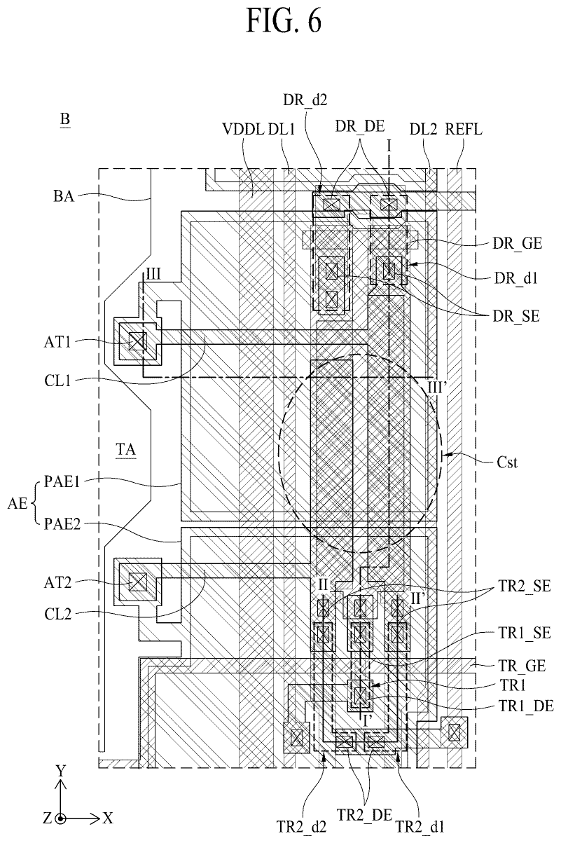

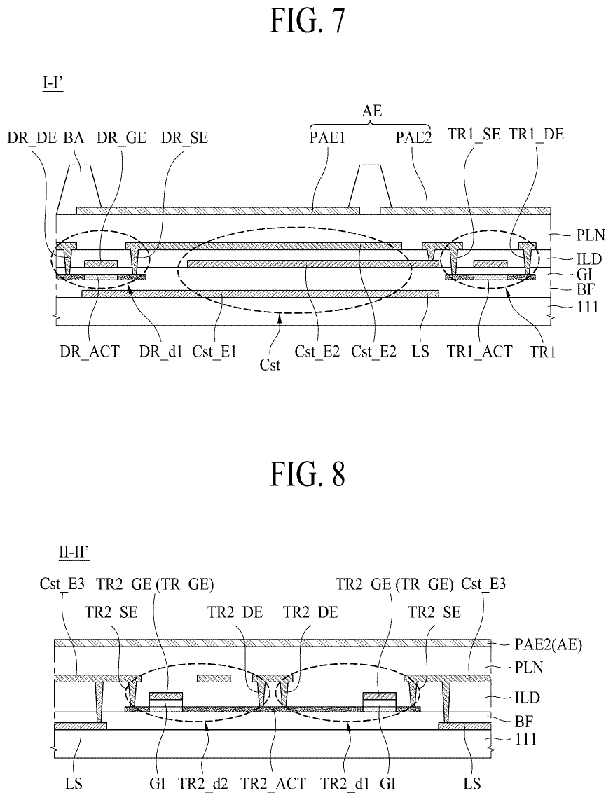

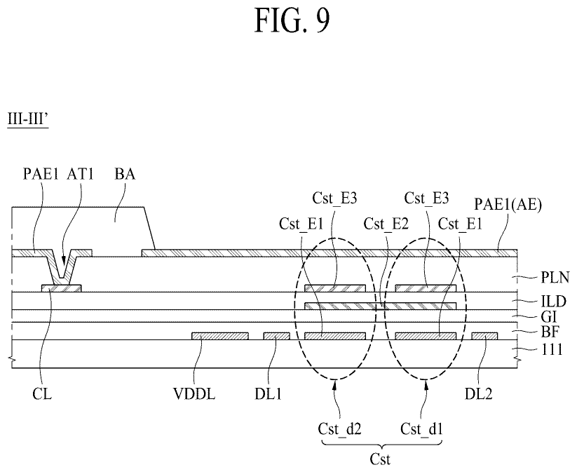

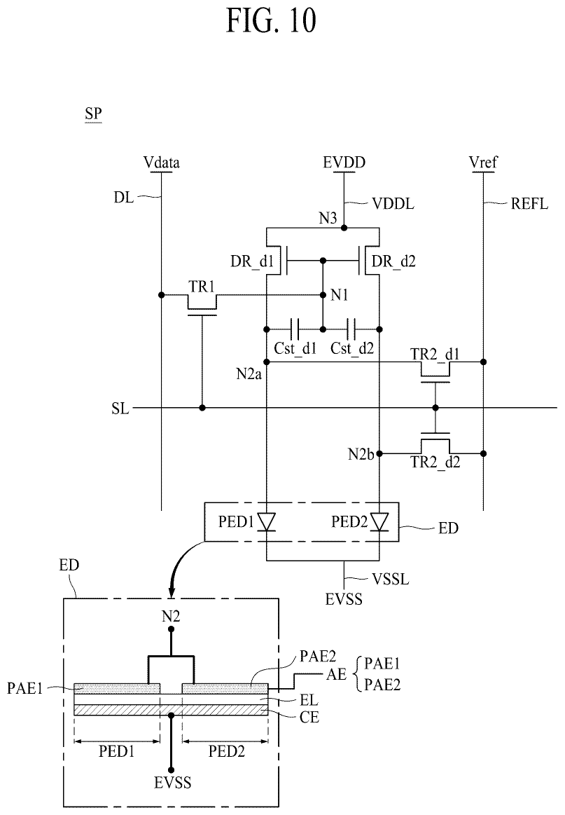

FIG. 4 illustrates a pixel of a light emitting display apparatus according to another aspect of the present disclosure. FIG. 5 illustrates an area A shown in FIG. 4 according to another aspect of the present disclosure. FIG. 6 illustrates an area B shown in FIG. 5 according to another aspect of the present disclosure. FIG. 7 is a cross-sectional view along line I-I′ of FIG. 6 according to another aspect of the present disclosure. FIG. 8 is a cross-sectional view along line II-II′ of FIG. 6 according to another aspect of the present disclosure. FIG. 9 is a cross-sectional view along line III-III′ of FIG. 6 according to another aspect of the present disclosure. FIG. 10 is a circuit diagram illustrating a subpixel of a light emitting display apparatus according to another aspect of the present disclosure.

Referring to FIGS. 4 to 10, each of pixels P of the light emitting display apparatus according to another aspect of the present disclosure may include a transmission area TA and a non-transmission area NTA in which a plurality of subpixels SP1, SP2, SP3, and SP4 representing different colors are disposed. For example, in FIGS. 4 to 9, each pixel P is illustrated as a transparent display panel including a transmission area TA, but aspects of the present disclosure are not limited thereto. Herein, each pixel P may be a light emitting display panel which does not include a transmission area TA.

Referring to FIG. 4, in each pixel P, the plurality of subpixels SP1, SP2, SP3, and SP4 may be disposed adjacent to each other in a first direction (or Y-axis direction) and a second direction (or X-axis direction). Also, the transmission area TA may be disposed adjacent to the plurality of subpixels SP1, SP2, SP3, and SP4 in the second direction (or X-axis direction). For example, the transmission area TA may be an area through which most of light incident from the outside passes, and the non-transmission area NTA may be an area which does not transmit most of light incident from the outside. For example, the transmission area TA may be an area in which the light transmittance is greater than a %, and the non-transmission area NTA may be a region in which the light transmittance is less than b %. Herein, ‘a’ may be a value greater than ‘b’. The light emitting display apparatus according to the aspect of the present disclosure may view an object or a background located on a rear surface (or back surface) of a display panel 110 through transmission areas TA.

The non-transmission area NTA may include a first non-transmission area NTA1, a second non-transmission area NTA2, and the plurality of subpixels SP1, SP2, SP3, and SP4.

The first non-transmission area NTA1 extends from the display panel 110 in the first direction (or Y-axis direction), and at least a portion of the first non-transmission area NTA1 may be disposed to overlap with emission areas EA1, EA2, EA3, and EA4 of each of the subpixels SP1, SP2, SP3, and SP4.

There may be the plurality of first non-transmission areas NTA1. The plurality of first non-transmission areas NTA1 may extend in the first direction (or Y-axis direction) and may be spaced apart from each other in the second direction (or X-axis direction). The two adjacent first non-transmission areas NTA1 may be arranged to be spaced apart from each other with the transmission area TA interposed therebetween. For example, the transmission area TA may be arranged between the two adjacent first non-transmission areas NTA1. At least one first signal line extending in the first direction (or Y-axis direction) may be disposed in the first non-transmission area NTA1. For example, the at least one first signal line may be disposed to overlap the first non-transmission area NTA1. For example, the at least one first signal line may include at least one of a pixel power line VDDL (or first power line), a common power line VSSL (or second power line), a reference line REFL, and data lines DL, but aspects of the present disclosure are not limited thereto.

The second non-transmission area NTA2 may extend in the second direction (or X-axis direction) in the display panel 110, and at least a portion of the second non-transmission area NTA2 may be disposed to overlap the emission areas EA1, EA2, EA3, and EA4 of each of the subpixels SP1, SP2, SP3, and SP4. For example, the second non-transmission area NTA2 may extend in the second direction (or X-axis direction) between the two adjacent first non-transmission areas NTA1. There may be the plurality of second non-transmission areas NTA2. The plurality of second non-transmission areas NTA2 may extend in the second direction (or X-axis direction) and may be spaced apart from each other in the first direction (or Y-axis direction). The two adjacent second non-transmission areas NTA2 may be arranged to be spaced apart from each other with the transmission area TA interposed therebetween. For example, the transmission area TA may be arranged between the two adjacent second non-transmission areas NTA2. At least one second signal line extending in the second direction (or X-axis direction) may be disposed in the second non-transmission area NTA2. For example, the at least one second signal line may be disposed to overlap the second non-transmission area NTA2. For example, the at least one second signal line may include a scan line SL (or gate line), but aspects of the present disclosure are not limited thereto.

Each pixel P is disposed in each intersection where the first non-transmission area NTA1 and the second non-transmission area NTA2 intersect, and each pixel P emits light to display an image. Each pixel P may include the emission area EA1, EA2, EA3, and EA4 which emits light in response to the plurality of subpixels SP1, SP2, SP3, and SP4 including a light emitting element. The emission area EA1, EA2, EA3, and EA4 may correspond to an area in which light is emitted from the pixel P. The emission areas EA1, EA2, EA3, and EA4 may be disposed to overlap pixel circuits of the plurality of subpixels SP1, SP2, SP3, and SP4. For example, the emission areas EA1, EA2, EA3, and EA4 may at least partially overlap the pixel circuits of the subpixels SP1, SP2, SP3, and SP4.

The first to fourth emission areas EA1, EA2, EA3, and EA4 corresponding to the plurality of subpixels SP1, SP2, SP3, and SP4 may emit light of different colors. For example, the first emission area EA1 may emit light of a first color such as green light, the second emission area EA2 may emit light of a second color such as blue light, the third emission area EA3 may emit light of a third color such as white light, and the fourth emission area EA4 may emit light of a fourth color such as red light, but aspects of the present disclosure are not limited thereto. For example, the plurality of subpixels SP1, SP2, SP3, and SP4 may be configured in a quad type arranged in the first direction (or Y-axis direction) and the second direction (or X-axis direction) or a stripe type arranged in the first direction (or Y-axis direction), but not limited thereto. The arrangement order or type of the plurality of subpixels may be variously changed.

Referring to FIGS. 5 to 10, the subpixel SP according to another aspect of the present disclosure may include the pixel circuit including at least one thin film transistor DR_d1, DR_d2, TR1, TR2_d1, and TR2_d2 and a storage capacitor Cst. For example, the at least one thin film transistor DR_d1, DR_d2, TR1, TR2_d1, and TR2_d2 may include a driving transistor DR_d1 and DR_d2, a first switching transistor TR1, and a second switching transistor TR2_d1 and TR2_d2. The subpixel SP may include the light emitting element ED for receiving a driving current through the pixel circuit and emitting light. For example, the light emitting element ED may include a first electrode AE (pixel electrode or anode electrode), an emission layer (or organic light emitting layer), and a second electrode CE (common electrode or cathode electrode). At least one power line and at least one signal line may be disposed in the subpixel SP. For example, the at least one power line may include a first power line VDDL (or pixel power line) extending in the first direction (or Y-axis direction) and a second power line VSSL (or common power line) extending in the first direction (or Y-axis direction). Also, the at least one signal line may include the data line DL and the reference line REFL extending in the first direction (or Y-axis direction) and the scan line (or gate line) extending in the second direction (or X-axis direction).

The subpixel SP according to another aspect of the present disclosure may include a plurality of divided light emitting areas. For example, the subpixel SP may include a first divided electrode PAE1 (or first pixel divided electrode) and a second divided electrode PAE2 (or second pixel divided electrode) spaced apart from each other in the first direction (or the Y-axis direction) and obtained by dividing the first electrode AE (pixel electrode or anode electrode) of the light emitting element ED. For example, the first divided electrode PAE1 and the second divided electrode PAE2 may be disposed to be adjacent to each other in the first direction. The second electrode CE of the light emitting element ED may be connected in common to the first divided electrode PAE1 and the second divided electrode PAE2. The second electrode CE receives the second power voltage EVSS from the common power line VSSL and applies the second power voltage EVSS to the first divided electrode PAE1 and the second divided electrode PAE2.

As shown in FIG. 10, the light emitting element ED of the subpixel SP may include the first electrode AE (pixel electrode or anode electrode), the emission layer EL (or organic light emitting layer), and the second electrode CE (common electrode or cathode electrode). The light emitting element ED may include a first partial light emitting element PED1 and a second partial light emitting element PED2. The first partial light emitting element PED1 and the second partial light emitting element PED2 may respectively correspond to the first divided electrode PAE1 and the second divided electrode PAE2 of the first electrode AE. For example, the first partial light emitting element PED1 may be composed of the emission layer EL and the second electrode CE which are overlapped with the first divided electrode PAE1. In addition, the second partial light emitting element PED2 may be composed of the emission layer EL and the second electrode CE which are overlapped with the second divided electrode PAE2. For example, as shown in FIG. 10, the emission layer EL and the second electrode CE may be commonly included in the first partial light emitting element PED1 and the second partial light emitting element PED2.

According to another aspect of the present disclosure, at least a portion of the at least one thin film transistor DR_d1, DR_d2, TR1, TR2_d1, and TR2_d2 according to another aspect of the present disclosure may be composed of a dual transistor connected to each of the first divided electrode PAE1 and the second divided electrode PAE2. For example, the dual transistor may include two thin film transistors, and may be expressed by terms such as a twin transistor, a pair transistor, a mirror transistor, and the like, but aspects of the present disclosure are not limited thereto. For example, the two thin film transistors sharing the gate electrode may be configured in a mirror structure. For example, the mirror structure may have a structure in which the two thin film transistors are arranged to face each other while being spaced apart from each other, and the two thin film transistors may be arranged symmetrically to each other in the first direction (or Y-axis direction) or the second direction (or X-axis direction), but not limited thereto.

The driving transistor DR_d1 and DR_d2 and the second switching transistor TR2_d1 and TR2_d2 among the at least one thin film transistor DR_d1, DR_d2, TR1, TR2_d1, and TR2_d2 may be formed in a dual transistor, and the first switching transistor TR1 may be formed in a single transistor. For example, the driving transistor DR_d1 and DR_d2 may include a first driving transistor DR_d1 and a second driving transistor DR_d2. Also, the second switching transistor TR2_d1 and TR2_d2 may include a first divided switching transistor TR2_d1 and a second divided switching transistor TR2_d2.

The driving transistor DR_d1 and DR_d2 according to another aspect of the present disclosure may include the first driving transistor DR_d1 and the second driving transistor DR_d2. For example, the first driving transistor DR_d1 may be connected to the first divided electrode PAE1, and the second driving transistor DR_d2 may be connected to the second divided electrode PAE2. For example, the first driving transistor DR_d1 and the second driving transistor DR_d2 may be disposed to overlap any one of the first divided electrode PAE1 and the second divided electrode PAE2 of the light emitting element ED. For example, the first driving transistor DR_d1 and the second driving transistor DR_d2 may be disposed to overlap the first divided electrode PAE1, but aspects of the present disclosure are not limited thereto.

The first driving transistor DR_d1 and the second driving transistor DR_d2 may have the mirror structure. For example, the mirror structure may be the structure in which the first and second driving transistors DR_d1 and DR_d2 are arranged to face each other while being spaced apart from each other, and the first and second driving transistors DR_d1 and DR_d2 may be arranged symmetrically to each other in the first direction (or Y-axis direction) or second direction (or X-axis direction), or may be arranged in the mirror shape, but is not limited thereto. The first driving transistor and the second driving transistor DR_d1 and DR_d2 may share the gate electrode DR_GE with each other. For example, the gate electrode DR_GE of each of the first driving transistor and the second driving transistor DR_d1 and DR_d2 may be connected in common. For example, the gate electrode DR_GE of the driving transistor DR_d1 and DR_d2 may extend in the second direction (or X-axis direction) on a substrate.

The respective drain electrodes DR_DE (one end or first source/drain electrode) of the first driving transistor DR_d1 and the second driving transistor DR_d2 may be connected to the same node. For example, the drain electrode DR_DE of each of the first driving transistor DR_d1 and the second driving transistor DR_d2 may be electrically connected to the first power voltage line VDDL (or pixel power line). The drain electrodes DR_DE of the first driving transistor DR_d1 and the second driving transistor DR_d2 may be configured in the mirror structure while being spaced apart from each other in the second direction (or X-axis direction). For example, the mirror structure may be the structure in which the drain electrodes DR_DE of the first driving transistor DR_d1 and the second driving transistor DR_d2 are arranged to face each other while being spaced apart from each other, and the drain electrodes DR_DE of the first driving transistor DR_d1 and the second driving transistor DR_d2 may be arranged symmetrically to each other in the first direction (or Y-axis direction) or the second direction (or X-axis direction), or may be arranged in the mirror shape, but not limited thereto. The source electrodes DR_SE (the other end or second source/drain electrode) of the respective first driving transistor DR_d1 and the second driving transistor DR_d2 may be connected to the different nodes. For example, the source electrode DR_SE of the first driving transistor DR_d1 may be electrically connected to the first divided electrode PAE1, and the source electrode DR_SE of the second driving transistor DR_d2 may be electrically connected to the second divided electrode PAE2. The source electrodes DR_SE of the first driving transistor DR_d1 and the second driving transistor DR_d2 may be configured in the mirror structure while being spaced apart from each other in the second direction (or X-axis direction). For example, the mirror structure may be the structure in which the source electrodes DR_SE of the first driving transistor DR_d1 and the second driving transistor DR_d2 are arranged to face each other while being spaced apart from each other, and the source electrodes DR_SE of the first driving transistor DR_d1 and the second driving transistor DR_d2 may be arranged symmetrically to each other in the first direction (or Y-axis direction) or the second direction (or X-axis direction), but not limited thereto.

As shown in FIG. 10, the respective source electrodes of the first driving transistor DR_d1 and the second driving transistor DR_d2 may be connected to the first storage capacitor Cst_d1 and the second storage capacitor Cst_d2. For example, the source electrode DR_SE of the first driving transistor DR_d1 may be connected to the first storage capacitor Cst_d1. The first storage capacitor Cst_d1 may extend in the first direction (or Y-axis direction) on the substrate. The first storage capacitor Cst_d1 may include a first electrode Cst_E1, a second electrode Cst_E2, and a third electrode Cst_E3 disposed at different layers on the substrate. For example, the source electrode DR_SE of the first driving transistor DR_d1 may be electrically connected to the third electrode Cst_E3 of the first storage capacitor Cst_d1. The first divided electrode PAE1 may be electrically connected to the first storage capacitor Cst_d1 and the first driving transistor DR_d1 through a first connection line CL1 extending in the second direction (or X-axis direction) from the third electrode Cst_E3 of the first storage capacitor Cst_d1. The first connection line CL1 may serve to repair the darkening of the first divided electrode PAE1. The first connection line CL1 is extended from the first storage capacitor Cst_d1 in the second direction and is electrically connected to the first divided electrode PAE1 through a first contact portion AT1.

The source electrode DR_SE of the second driving transistor DR_d2 may be connected to the second storage capacitor Cst_d2. The second storage capacitor Cst_d2 may extend in the first direction (or Y-axis direction) on the substrate. The second storage capacitor Cst_d2 may include a first electrode Cst_E1, a second electrode Cst_E2, and a third electrode Cst_E3 disposed at different layers on the substrate. As shown in FIG. 9, the first electrode Cst_E1 of the first storage capacitor Cst_d1 and the first electrode Cst_E1 of the second storage capacitor Cst_d2 may be disposed on the same layer, and may be spaced apart from each other. Similarly, the third electrode Cst_E3 of the first storage capacitor Cst_d1 and the third electrode Cst_E3 of the second storage capacitor Cst_d2 may be disposed on the same layer, and may be spaced apart from each other. For example, the second electrode Cst_E2 may be disposed between the first electrode Cst_E1 and the third electrode Cst_E3. For example, the source electrode DR_SE of the second driving transistor DR_d2 may be electrically connected to the first electrode Cst_E1 of the second storage capacitor Cst_d2. For example, the source electrode DR_SE of the second driving transistor DR_d2 may be electrically connected to the first electrode Cst_E1 of the second storage capacitor Cst_d2 disposed on the other layer of the substrate, which is different layer from that of the first connection line CL1, through a contact hole to bypass a portion overlapping the first connection line CL1 extending from the third electrode Cst_E3 of the first storage capacitor Cst_d1. The second divided electrode PAE2 may be electrically connected to the second storage capacitor Cst_d2 and the second driving transistor DR_d2 through a second connection line CL2 extending in the second direction (or X-axis direction) from the third electrode Cst_E3 of the second storage capacitor Cst_d2. The second connection line CL2 serve to repair the darkening of the second divided electrode PAE2. The second connection line CL2 is extended from the second storage capacitor Cst_d2 in the second direction and is electrically connected to the second divided electrode PAE2 through a second contact portion AT2.

The first switching transistor TR1 according to another aspect of the present disclosure may be configured in the single transistor. For example, the first switching transistor TR1 may be disposed between the second switching transistors TR2_d1 and TR2_d2 configured in the dual transistor. For example, the first switching transistor TR1 may be disposed to overlap any one of the first divided electrode PAE1 and the second divided electrode PAE2 of the light emitting element ED. For example, the first switching transistor TR1 may be disposed to overlap the second divided electrode PAE2, but aspects of the present disclosure are not limited thereto.

The first switching transistor TR1 and the second switching transistors TR2_d1 and TR2_d2 may share the gate electrode TR_GE. For example, the gate electrode TR_GE of the first switching transistor TR1 may be commonly connected to the gate electrode TR_GE of the second switching transistors TR2_d1 and TR2_d2. For example, the gate electrode TR_GE of the first and second switching transistors TR1, TR2_d1, and TR2_d2 may extend in the second direction (or X-axis direction) on the substrate.

The drain electrode TR1_DE of the first switching transistor TR1 may be electrically connected to the data line DL1.

The source electrode TR1_SE of the first switching transistor TR1 may be connected to the storage capacitor Cst. For example, the source electrode TR1_SE of the first switching transistor TR1 may be electrically connected to the second electrode Cst_E2 of the storage capacitor Cst. The source electrode TR1_SE of the first switching transistor TR1 may be disposed between the source electrodes TR2_SE of the second switching transistors TR2_d1 and TR2_d2.

The second switching transistor TR2_d1 and TR2_d2 according to another aspect of the present disclosure may include a first divided switching transistor TR2_d1 and a second divided switching transistor TR2_d2. For example, the first divided switching transistor TR2_d1 may be connected to the first divided electrode PAE1, and the second divided switching transistor TR2_d2 may be connected to the second divided electrode PAE2. For example, the first divided switching transistor TR2_d1 and the second divided switching transistor TR2_d2 may be disposed to overlap any one of the first divided electrode PAE1 and the second divided electrode PAE2 of the light emitting element ED. For example, the first divided switching transistor TR2_d1 and the second divided switching transistor TR2_d2 may be disposed to overlap the second divided electrode PAE2, but aspects of the present disclosure are not limited thereto.

The first divided switching transistor TR2_d1 and the second divided switching transistor TR2_d2 may be configured in the mirror structure. For example, the mirror structure may be the structure in which the first and second divided switching transistors TR2_d1 and TR2_d2 are arranged to face each other while being spaced apart from each other, and the first and second divided switching transistors TR2_d1 and TR2_d2 may be arranged symmetrically to each other in the first direction (or Y-axis direction) or second direction (or X-axis direction), or may be arranged in the mirror shape, but not limited thereto. The first divided switching transistor TR2_d1 and the second divided switching transistor TR2_d2 may share the gate electrode TR_GE with each other. For example, the gate electrode TR_GE of the first divided switching transistor TR2_d1 and the gate electrode TR_GE of the second divided switching transistor TR2_d2 may be connected in common. For example, the gate electrode TR_GE of the second switching transistors TR2_d1 and TR2_d2 may extend in the second direction (or X-axis direction) on the substrate.

The drain electrodes TR2_DE (one end or first source/drain electrode) of the first divided switching transistor TR2_d1 and the second divided switching transistor TR2_d2 may be connected to the same node. For example, the drain electrode TR2_DE of each of the first divided switching transistor TR2_d1 and the second divided switching transistor TR2_d2 may be electrically connected to the reference line REFL. The drain electrode TR2_DE of the first divided switching transistor TR2_d1 and the drain electrode TR2_DE of the second divided switching transistor TR2_d2 may have the mirror structure spaced apart from each other in the second direction (or X-axis direction). For example, the mirror structure may be the structure in which the drain electrodes TR2_DE of the first divided switching transistor TR2_d1 and the second divided switching transistor TR2_d2 are arranged to face each other while being spaced apart from each other, and the drain electrodes TR2_DE of the first divided switching transistor TR2_d1 and the second divided switching transistor TR2_d2 may be arranged symmetrically to each other in the first direction (or Y-axis direction) or second direction (or X-axis direction), or may be arranged in the mirror shape, but not limited thereto.

The source electrodes TR2_SE (the other end or second source/drain electrode) of the first divided switching transistor TR2_d1 and the second divided switching transistor TR2_d2 may be connected to the different nodes. For example, the source electrode TR2_SE of the first divided switching transistor TR2_d1 may be electrically connected to the first divided electrode PAE1, and the source electrode TR2_SE of the second divided switching transistor TR2_d2 may be electrically connected to the second divided electrode PAE2. For example, the source electrode TR2_SE of the first divided switching transistor TR2_d1 may be connected to the node N2a between the first storage capacitor Cst_d1 and the first divided electrode PAE1, and the source electrode TR2_SE of the second divided switching transistor TR2_d2 may be connected to the node N2b between the second storage capacitor Cst_d2 and the second divided electrode PAE2. The source electrodes TR2_SE of the first divided switching transistor TR2_d1 and the second divided switching transistor TR2_d2 may have the mirror structure spaced apart from each other in the second direction (or X-axis direction). For example, the mirror structure may be the structure in which the source electrodes TR2_SE of the first divided switching transistor TR2_d1 and the second divided switching transistor TR2_d2 are arranged to face each other while being spaced apart from each other, and the source electrodes TR2_SE of the first divided switching transistor TR2_d1 and the second divided switching transistor TR2_d2 may be arranged symmetrically to each other in the first direction (or Y-axis direction) or second direction (or X-axis direction), or may be arranged in the mirror shape, but not limited thereto.

The source electrode TR2_SE of the first divided switching transistor TR2_d1 may be connected to the first storage capacitor Cst _d1. For example, the source electrode TR2_SE of the first divided switching transistor TR2_d1 may be electrically connected to the third electrode Cst_E3 of the first storage capacitor Cst_d1.

The source electrode TR2_SE of the second divided switching transistor TR2_d2 may be connected to the second storage capacitor Cst_d2. For example, the source electrode TR2_SE of the second divided switching transistor TR2_d2 may be electrically connected to the third electrode Cst_E3 of the second storage capacitor Cst_d2.

Referring to FIGS. 7 to 9, at least one of a light shielding layer LS, the first power line VDDL, the second power line VSSL, the data line DL1 and DL2, and the reference line REFL may be disposed on the substrate 111. For example, the light shielding layer LS may serve to block external light incident on an active layer of the driving transistor DR. The light shielding layer LS may be formed in a single-layered or multi-layered structure of any one of molybdenum Mo, aluminum Al, chromium Cr, gold Au, titanium Ti, nickel Ni, neodymium Nd, and copper Cu, or an alloy thereof. For example, at least one of the first power line VDDL, the second power line VSSL, the data line DL1 and DL2, and the reference line REFL disposed on the substrate 111 may be formed of the same material on the same layer as the light shielding layer LS, but aspects of the present disclosure are not limited thereto. In addition, as shown in FIG. 9, the first electrode Cst_E1 of the storage capacitors Cst_d1 and Cst_d2 may be disposed on the substrate 111. The first electrode Cst_E1 of the storage capacitors Cst_d1 and Cst_d2 may be formed of the same material on the same layer as the light shielding layer LS. For example, the storage capacitors Cst_d1 and Cst_d2 may include the first storage capacitor Cst_d1 and the second storage capacitor Cst_d2. The first electrodes Cst_E1 of the respective first storage capacitor Cst_d1 and the second storage capacitor Cst_d2 may be spaced apart from each other.

A buffer layer BF may be disposed on the substrate 111 on which at least one signal line VDDL, VSSL, DL, and REFL, and the light shielding layer LS are disposed. The buffer layer BF protects the thin film transistor from moisture penetrating through the substrate 111 vulnerable to moisture permeation. The buffer layer BF may be configured in a single-layered structure or multi-layered structure including an inorganic insulating material such as silicon oxide SiOₓ, silicon nitride SiNₓ, aluminum oxide Al₂O₃, and the like.

At least one thin film transistor DR_d1, DR_d2, TR1, TR2_d1, and TR2_d2 and the storage capacitor Cst_d1 and Cst_d2 may be disposed on the buffer layer BF. For example, the at least one thin film transistor DR_d1, DR_d2, TR1, TR2_d1, and TR2_d2 may include the active layer DR_ACT, TR1_ACT, and TR2_ACT, the gate electrode RE_GE and TR_GE, the drain electrode DR_DE, TR1_DE, and TR2_DE, and the source electrode TR_SE, TR1_SE, and TR2_SE. The storage capacitor Cst_d1 and Cst_d2 may include the first electrode Cst_E1, the second electrode Cst_E2, and the third electrode Cst_E3.

The active layer DR_ACT, TR1_ACT, and TR2_ACT on the buffer layer BF may be formed of an oxide semiconductor material or a silicon-based semiconductor material. For example, the active layer DR_ACT, TR1_ACT, and TR2_ACT may be composed of oxide semiconductor such as indium gallium zinc oxide IGZO, indium gallium oxide IGO, and indium tin zinc oxide ITZO. For example, the active layer DR_ACT, TR1_ACT, and TR2_ACT composed of the oxide semiconductor may vary according to the content of oxygen. When the content of oxygen decreases, conductivity of the oxide semiconductor may be increased and become conductive. A gate insulating layer GI may be disposed between the active layer DR_ACT, TR1_ACT, and TR2_ACT and the gate electrode DR_GE and TR_GE.

The gate electrode DR_GE and TR_GE of the at least one thin film transistor DR_d1, DR_d2, TR1, TR2_d1, and TR2_d2 may be arranged on the gate insulation layer GI. For example, the gate electrode DR_GE and TR_GE may be patterned together with the gate insulating layer GI, and the gate insulating layer GI may be patterned only in an area where the gate electrode DR_GE and TR_GE is arranged, but aspects of the present disclosure are not limited thereto. In addition, as shown in FIG. 9, the second electrode Cst_E2 of the storage capacitor Cst_d1 and Cst_d2 may be disposed on the gate insulating layer GI. The second electrode Cst_E2 of the storage capacitor Cst_d1 and Cst_d2 may be formed of the same material on the same layer as the gate electrode DR_GE and TR_GE. For example, the storage capacitor Cst_d1 and Cst_d2 may include the first storage capacitor Cst_d1 and the second storage capacitor Cst_d2. The second electrode Cst_E2 of the storage capacitor Cst_d1 and Cst_d2 may be commonly configured in the first storage capacitor Cst_d1 and the second storage capacitor Cst_d2.

An interlayer insulating layer ILD may be disposed on the gate insulating layer GI on which the gate electrode DR_GE and TR_GE and the second electrode Cst_E2 of the storage capacitor Cst_d1 and Cst_d2 are disposed. For example, the interlayer insulating layer ILD may be disposed between the gate electrode DR_GE and TR_GE of at least one thin film transistor DR_d1, DR_d2, TR1, TR2_d1, and TR2_d2 and the source/drain electrode DR_DE, DR_SE, TR1_DE, TR1_SE, TR2_DE, and TR2_SE. The interlayer insulating layer ILD may be configured in a single-layered structure or multi-layered structure including an inorganic insulating material such as silicon oxide SiOₓ, silicon nitride SiNₓ, aluminum oxide Al₂O₃, and the like. The source/drain electrode DR_DE, DR_SE, TR1_DE, TR1_SE, TR2_DE, and TR2_SE of the at least one thin film transistor DR_d1, DR_d2, TR1, TR2_d1, and TR2_d2 may be disposed on the interlayer insulating layer ILD. Also, as shown in FIG. 9, the third electrode Cst_E3 of the storage capacitor Cst_d1 and Cst_d2 may be disposed on the interlayer insulating layer ILD. The third electrode Cst_E3 of the storage capacitor Cst_d1 and Cst_d2 may be formed of the same material in the same layer as the source/drain electrode DR_DE, DR_SE, TR1_DE, TR1_SE, TR2_DE, and TR2_SE. For example, the storage capacitor Cst_d1 and Cst_d2 may include the first storage capacitor Cst_d1 and the second storage capacitor Cst_d2. The third electrodes Cst_E3 of the respective first storage capacitor Cst_d1 and the second storage capacitor Cst_d2 may be spaced apart from each other. For example, the third electrodes Cst_E3 of the respective first storage capacitor Cst_d1 and the second storage capacitor Cst_d2 may be arranged symmetrically to each other, or may be arranged in the mirror shape, but not limited thereto.

A planarization layer PLN may be disposed on the interlayer insulating layer ILD in which the source/drain electrode DR_DE, DR_SE, TR1_DE, TR1_SE, TR2_DE, and TR2_SE and the third electrodes Cst_E3 of the storage capacitor Cst_d1 and Cst_d2 are disposed. The planarization layer PLN may be an organic insulating layer for planarizing a step difference caused by the at least one thin film transistor DR_d1, DR_d2, TR1, TR2_d1, and TR2_d2 and the storage capacitor Cst_d1 and Cst_d2. For example, the planarization layer PLN may be formed of an organic material such as acryl resin, epoxy resin, phenolic resin, polyamide resin, polyimide resin, or the like.

The first electrode AE, the emission layer EL, and the second electrode CE of the light emitting element ED and a bank layer BA may be disposed on the planarization layer PLN. For example, the bank layer BA may be formed of an organic material such as acryl resin, epoxy resin, phenolic resin, polyamide resin, polyimide resin, or the like.

Referring to FIG. 7, the first electrode AE of the light emitting element ED may include the first divided electrode PAE1 and the second divided electrode PAE2. The bank layer BA may be formed on the planarization layer PLN on which the first divided electrode PAE1 and the second divided electrode PAE2 are disposed. The bank layer BA covers edges of each of the first divided electrode PAE1 and the second divided electrode PAE2, and may be configured to expose a portion of each of the first divided electrode PAE1 and the second divided electrode PAE2. In addition, the driving thin film transistor DR_d1 and DR_d2 may be disposed to overlap the first divided electrode PAE1, and the first switching transistor TR1 may be disposed to overlap the second divided electrode PAE2.

Referring to FIG. 8, the second switching transistor TR2_d1 and TR2_d2 may be disposed to overlap the second divided electrode PAE2. The second switching transistor TR2_d1 and TR2_d2 may include the first divided switching transistor TR2_d1 and the second divided switching transistor TR2_d2, and the first divided switching transistor TR2_d1 and the second divided switching transistor TR2_d2 may have the mirror structure.

Referring to FIG. 9, the storage capacitor Cst_d1 and Cst_d2 may be disposed to overlap the first divided electrode PAE1. The storage capacitor Cst_d1 and Cst_d2 may include the first storage capacitor Cst_d1 and the second storage capacitor Cst_ d2, and the first storage capacitor Cst_d1 and the second storage capacitor Cst_d2 may have the mirror structure. For example, the mirror structure may have the structure in which the first and second storage capacitors Cst_d1 and Cst_d2 are arranged to face each other while being spaced apart from each other, and the first and second storage capacitors Cst_d1 and Cst_d2 may be arranged symmetrically to each other in the first direction (or Y-axis direction) or second direction (or X-axis direction), or may be arranged in the mirror shape, but not limited thereto. In addition, the first divided electrode PAE1 may be electrically connected to the connection line CL through a first contact portion AT1 passing through the planarization layer PLN.

Referring to FIG. 10, the pixel circuit of the subpixel SP according to another aspect of the present disclosure may include the driving transistor DR_d1 and DR_d2, the first switching transistor TR1, the second switching transistor TR2_d1 and TR2_d2, and the storage capacitor Cst_d1 and Cst_d2. Also, the first electrode AE of the light emitting element ED of the subpixel SP may be divided into the first divided electrode PAE1 and the second divided electrode PAE2, whereby the light emitting element ED of the subpixel SP may be composed of the first divided light emitting element PED1 and the second divided light emitting element PED2.

The driving transistor DR_d1 and DR_d2 may be configured in a dual transistor connected to each of the first divided electrode PAE1 and the second divided electrode PAE2. The driving transistor DR_d1 and DR_d2 may include the first driving transistor DR_d1 and the second driving transistor DR_d2. The driving transistor DR_d1 and DR_d2 includes a first node N1 to which a data voltage Vdata is applied, a second node N2a and N2b connected to each of the first divided electrode PAE1 and the second divided electrode PAE2 of the first divided light emitting element PED1 and the second divided light emitting element PED2, and a third node N3 connected to the pixel power line VDDL (or first power line) and supplied with first power supply voltage EVDD (or pixel power voltage). For example, the first driving transistor DR_d1 and the second driving transistor DR_d2 may be commonly connected to the first node N1 and the third node N3. In addition, the first driving transistor DR_d1 may be connected to the second node N2a connected to the first divided electrode PAE1, and the second driving transistor DR_d2 may be connected to the second node N2b connected to the second divided electrode PAE2.

The first switching transistor TR1 may be composed of a single transistor. The first switching transistor TR1 may switch an electrical connection between the data line DL and the first node N1. For example, the first switching transistor TR1 may control an electrical connection between the data line DL and the first node N1 based on the scan signal SCAN applied through the scan line SL (or gate line).

The second switching transistors TR2_d1 and TR2_d2 may be composed of the dual transistor connected to the first divided electrode PAE1 and the second divided electrode PAE2, respectively. The second switching transistors TR2_d1 and TR2_d2 may include the first divided switching transistor TR2_d1 and the second divided switching transistor TR2_d2. The second switching transistors TR2_d1 and TR2_d2 may switch an electrical connection between each of the first and second divided electrodes PAE1 and PAE2 and the reference line REFL. For example, the second switching transistors TR2_d1 and TR2_d2 may control an electrical connection between the first and second divided electrodes PAE1 and PAE2 and the reference line REFL based on the scan signal applied through the scan line SL (or gate line).

The first divided switching transistor TR2_d1 and the second divided switching transistor TR2_d2 are commonly connected to the scan line SL, and one end of each of the first divided switching transistor TR2_d1 and the second divided switching transistor TR2_d2 may be commonly connected to the reference line REFL. Also, the other end of the first divided switching transistor TR2_d1 may be connected to the second node N2a connected to the first divided electrode PAE1, and the other end of the second divided switching transistor TR2_d2 may be connected to the second node N2b connected to the second divided electrode PAE2.

The storage capacitor Cst_d1 and Cst_d2 may include the first storage capacitor Cst_d1 and the second storage capacitor Cst_d2 respectively corresponding to the first driving transistor DR_d1 and the first divided electrode PAE1, and the second driving transistor DR_d2 and the second divided electrode PAE2. One end of the first storage capacitor Cst_d1 is connected to the first node N1, and the other end of the first storage capacitor Cst_d1 is connected to the second node N2a connected to the first divided electrode PAE1. Also, one end of the second storage capacitor Cst_d2 may be connected to the first node N1, and the other end of the second storage capacitor Cst_d2 may be connected to the second node N2b connected to the second divided electrode PAE2.

In the light emitting display apparatus according to another aspect of the present disclosure, a repair detection voltage may be applied through the reference line REFL during a repair detection period.

The repair detection voltage applied from the reference line REFL during the repair detection period is stored in each of the first storage capacitor Cst_d1 and the second storage capacitor Cst_d2 through the turned-on first divided switching transistor TR2_d1 and the second divided switching transistor TR2_d2, and the first driving transistor DR_d1 and the second driving transistor DR_d2 are driven by the stored voltage, whereby it is possible to independently drive the first divided light emitting element PED1 and the second divided light emitting element PED2. For example, the supply of the data voltage Vdata may be stopped during the repair detection period.

Whether at least one of the first divided light emitting element PED1 and the second divided light emitting element PED2 is defective (or short-circuit) during the repair detection period may be determined based on the light-emitting driving of each of the first divided light emitting element PED1 and the second divided light emitting element PED2. For example, whether at least one of the first divided light emitting element PED1 and the second divided light emitting element PED2 is defective (or short-circuit) may be determined based on the brightness by the light-emitting driving of each of the first divided light emitting element PED1 and the second divided light emitting element PED2. For example, if the brightness of one of the first divided light emitting element PED1 and the second divided light emitting element PED2 is weaker than a preset threshold brightness, it may be determined that a defect (or short-circuit) is generated in the divided light emitting element having a weak brightness.

According to another aspect of the present disclosure, when it is determined that a defect (or short-circuit) is generated in any one divided light emitting element of the first divided light emitting element PED1 and the second divided light emitting element PED2, the connection line CL connected to the divided light emitting element with the defect or the connection portion of the divided electrode may be cut by applying a laser or physical force, so that the divided light emitting element with the defect may be darkened and the remaining divided light emitting element may be normally operated.

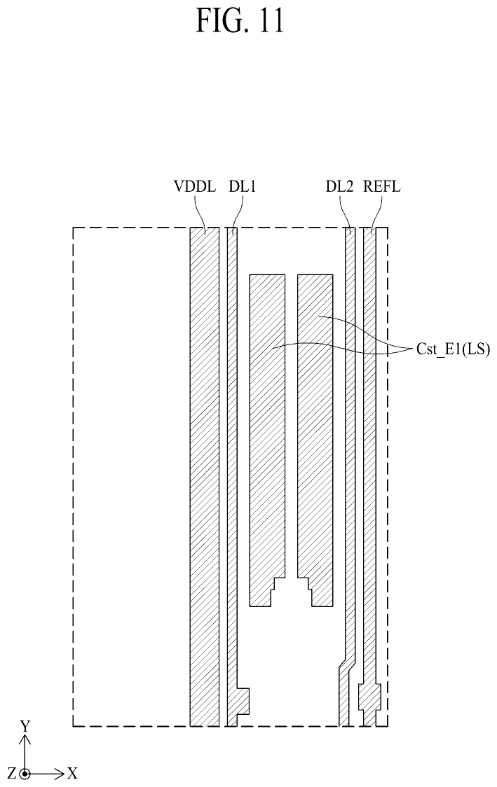

FIGS. 11 to 16 illustrate a method of forming the subpixel of the light emitting display apparatus according to another aspect of the present disclosure.

Referring to FIG. 11, the light shielding layer LS may be formed on the substrate, and the first power line VDDL, the data line DLI and DL2, the reference line REFL, and the first electrode Cst_E1 of the storage capacitor Cst, which are made of the same material as the light shielding layer LS, may be formed on the substrate. For example, the first power line VDDL, the data line DL1 and DL2, and the reference line REFL may be formed to extend in the first direction (or Y-axis direction) on the substrate. In addition, the first electrode Cst_E1 of the storage capacitor Cst may be formed to extend in the first direction. Also, the storage capacitor Cst may include the first storage capacitor Cst_d1 and the second storage capacitor Cst_d2, and the first electrodes of the respective first storage capacitor Cst_d1 and second storage capacitor Cst_d2 may have the mirror structure spaced apart from each other in the second direction (or X-axis direction). For example, the mirror structure may be the structure in which the first electrodes Cst_E1 of the first and second storage capacitors Cst_d1 and Cst_d2 are arranged to face each other while being spaced apart from each other, and the first electrodes Cst_E1 of the first and second storage capacitors Cst_d1 and Cst_d2 may be arranged symmetrically to each other in the first direction (or Y-axis direction) or second direction (or X-axis direction), or may be arranged in the mirror shape, but not limited thereto.

A buffer layer BF may be formed on the substrate to cover the light shielding layer LS, the first power line VDDL, the data line DL1 and DL2, the reference line REFL, and the first electrode Cst_E1 of the storage capacitor Cst.

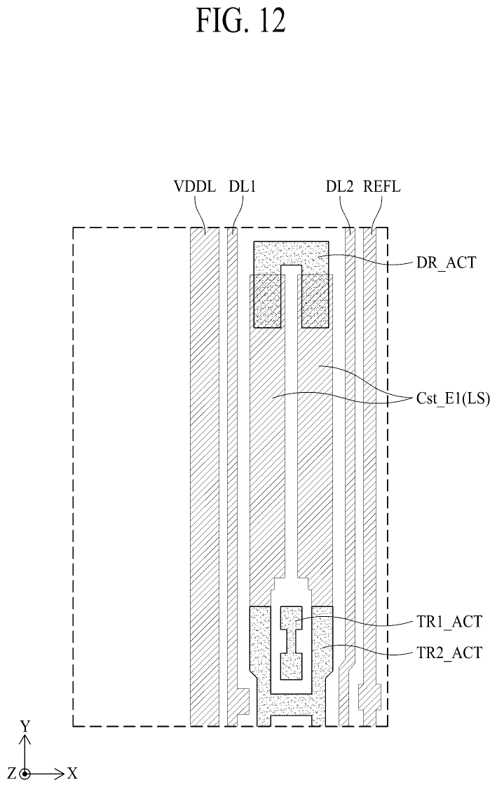

Referring to FIG. 12, an active layer DR_ACT, TR1_ACT, and TR2_ACT of at least one thin film transistor DR_d1, DR_d2, TR1, TR2_d1, and TR2_d2 may be formed on the buffer layer BF. The active layer DR_ACT of the driving thin film transistor DR_d1 and DR_d2 may be formed to have the mirror structure in the second direction (or X-axis direction). For example, the mirror structure may be the structure in which the active layers DR_ACT of the driving thin film transistors DR_d1 and DR_d2 are arranged to face each other while being spaced apart from each other, and the active layers DR_ACT of the driving thin film transistors DR_d1 and DR_d2 may be arranged symmetrically to each other in the first direction (or Y-axis direction) or second direction (or X-axis direction), or may be arranged in the mirror shape, but not limited thereto. Also, at least a portion of the active layer DR_ACT of the driving thin film transistor DR_d1 and DR_d2 may be formed to overlap the light shielding layer LS. The active layer TR2_ACT of the second switching transistor TR2_d1 and TR2_d2 may be formed to have the mirror structure in the second direction (or X-axis direction). For example, the mirror structure may be the structure in which the active layers TR2_ACT of the second switching transistor TR2_d1 and TR2_d2 are arranged to face each other while being spaced apart from each other, and the active layers TR2_ACT of the second switching transistor TR2_d1 and TR2_d2 may be arranged symmetrically to each other in the first direction (or Y-axis direction) or second direction (or X-axis direction), or may be arranged in the mirror shape, but not limited thereto. Also, the active layer TR1_ACT of the first switching transistor TR1 may be formed between the active layers TR2_ACT of the second switching transistor TR2_d1 and TR2_d2.

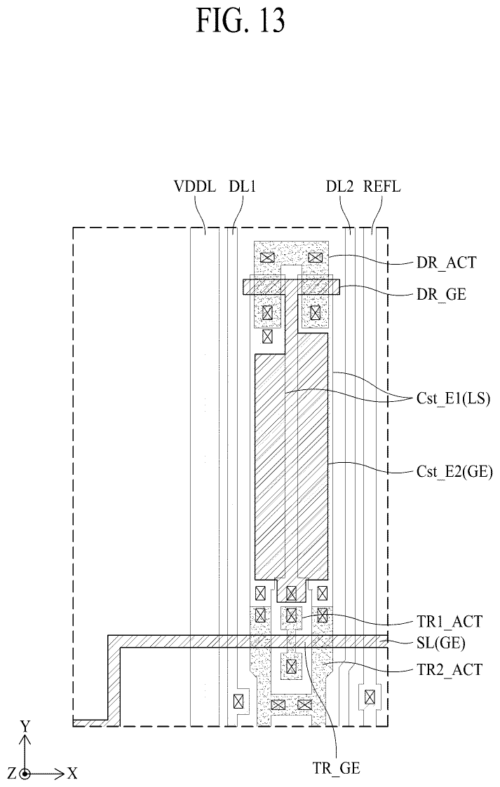

Referring to FIG. 13, a gate insulating layer GI is formed on the active layer DR_ACT, TR1_ACT, and TR2_ACT, and the gate electrode DR_GE and TR_GE of the at least one thin film transistor DR_d1, DR_d2, TR1, TR2_d1, and TR2_d2, the second electrode Cst_E2 of the storage capacitor Cst, and the scan line SL may be formed on the gate insulating layer GI. For example, at least a portion of the scan line SL may be formed to extend in the second direction (or X-axis direction) on the substrate, and at least a portion of the scan line SL may be arranged to overlap the active layers TR1_ACT and TR2_ACT of the first and second switching transistors TR1, TR2_d1, and TR2_d2. The scan line SL overlapped with the active layer TR1_ACT and TR2_ACT may be composed of the gate electrode DR_GE and TR_GE of the first and second switching transistors TR1, TR2_d1, and TR2_d2. Also, the second electrode Cst_E2 of the storage capacitor Cst may be disposed to overlap the first electrode Cst_E1 of the storage capacitor Cst. The second electrode Cst_E2 of the storage capacitor Cst may be formed to be commonly overlapped with the first electrode Cst_E1 of the first storage capacitor Cst_d1 and the second storage capacitor Cst_d2. In addition, the gate electrode DR_GE of the driving transistor DR_d1 and DR_d2 may extend from an upper end of the second electrode Cst_E2 of the storage capacitor Cst, and the gate electrode DR_GE of the driving transistor DR_d1 and DR_d2 may protrude from both sides of the second direction (or X-axis direction) in a portion overlapping with the active layer DR_ACT of the driving transistor DR_d1 and DR_d2. Also, contact holes for the electrical connection of the at least one thin film transistor DR_d1, DR_d2, TR1, TR2_d1, and TR2_d2 may be formed in the buffer layer BF and the gate insulation layer GI.

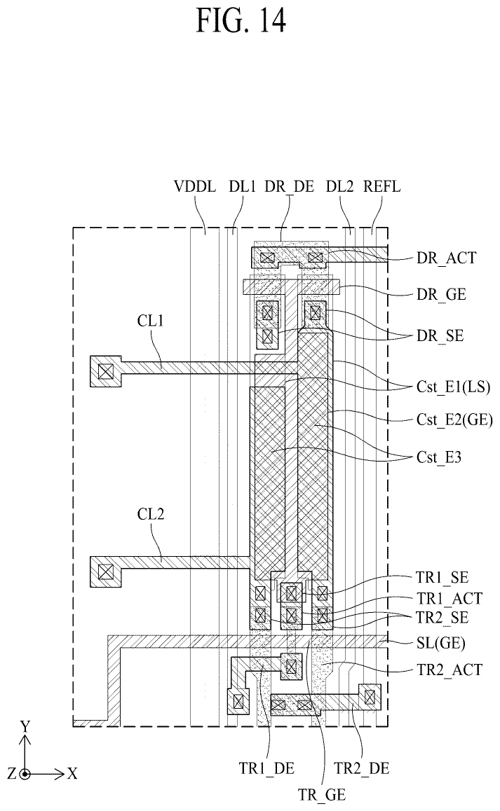

Referring to FIG. 14, an interlayer insulating layer ILD is formed on the gate electrode DR_GE and TR_GE, the second electrode Cst_E2 of the storage capacitor Cst, and the scan line SL. The source/drain electrode DR_DE, DR_SE, TR1_DE, TR1_SE, TR2_DE, and TR2_SE of the at least one thin film transistor DR_d1, DR_d2, TR1, TR2_d1, and TR2_d2, the third electrode Cst_E3 of the storage capacitor Cst, and the connection line CL1 and CL2 may be formed on the interlayer insulating layer ILD. The third electrode Cst_E3 of the storage capacitor Cst may be formed to extend in the first direction. The third electrodes Cst_E3 of the respective first storage capacitor Cst_d1 and second storage capacitor Cst_d2 may be formed in the mirror structure spaced apart from each other in the second direction (or X-axis direction). For example, the mirror structure may be the structure in which the third electrodes Cst_E3 of the first and second storage capacitors Cst_d1 and Cst_d2 are arranged to face each other while being spaced apart from each other, and the third electrodes Cst_E3 of the first and second storage capacitors Cst_d1 and Cst_d2 may be arranged symmetrically to each other in the first direction (or Y-axis direction) or second direction (or X-axis direction), or may be arranged in the mirror shape, but not limited thereto. Also, the source/drain electrode DR_DE, DR_SE, TR1_DE, TR1_SE, TR2_DE, and TR2_SE of the at least one thin film transistor DR_d1, DR_d2, TR1, TR2_d1, and TR2_d2 may be connected to the active layer DR_ACT, TR1_ACT, and TR2_ACT of the at least one thin film transistor DR_d1, DR_d2, TR1, TR2_d1, and TR2_d2 through the contact hole of the buffer layer BF and the gate insulating layer GI. Also, a portion of the source/drain electrode DR_DE, DR_SE, TR1_DE, TR1_SE, TR2_DE, and TR2_SE of the at least one thin film transistor DR_d1, DR_d2, TR1, TR2_d1, and TR2_d2 may protrude from the third electrode Cst_E3 of the storage capacitor Cst. In addition, the connection line CL1 and CL2 may be formed to extend in the second direction (or X-axis direction) from each of the first storage capacitor Cst_d1 and the second storage capacitor Cst_D2. For example, the third electrode Cst_E3 of the second storage capacitor Cst_d2 may be formed not to overlap the first connection line CL1.

A planarization layer PLN may be formed on the interlayer insulating layer ILD on which the source/drain electrode DR_DE, DR_SE, TR1_DE, TR1_SE, TR2_DE, and TR2_SE of the at least one thin film transistor DR_d1, DR_d2, TR1, TR2_d1, and TR2_d2, the third electrode Cst_E3 of the storage capacitor Cst, and the connection line CL1 and CL2 are disposed. In the planarization layer PLN, there may be the contact holes for providing the contact portion of the connection line CL1 and CL2.

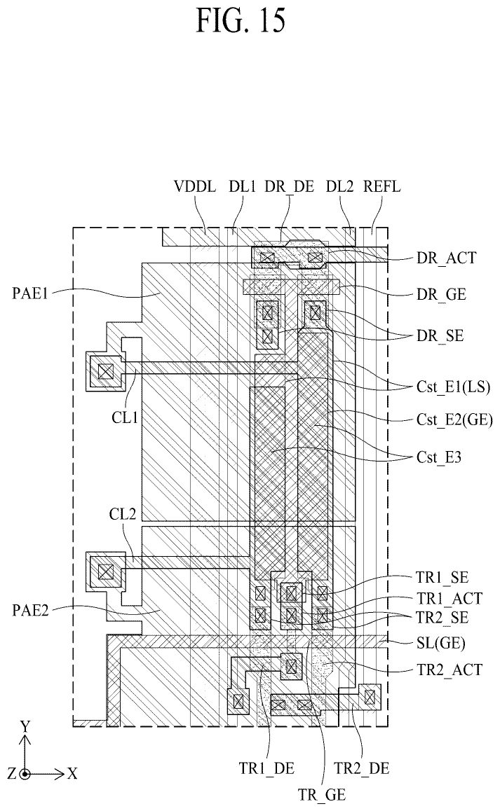

Referring to FIG. 15, the first electrode AE of the light emitting element ED may be formed on the planarization layer PLN. The light emitting element ED may be composed of the first divided light emitting element PED1 and the second divided light emitting element PED2. The first electrode AE may include the first divided electrode PAE1 and the second divided electrode PAE2 which are spaced apart from each other in the first direction (or Y-axis direction) and are adjacent to each other. The first divided electrode PAE1 may be electrically connected to the first connection line CL1 through the contact hole passing through the planarization layer PLN, and the second divided electrode PAE2 may be electrically connected to the second connection line CL2 through the contact hole passing through the planarization layer PLN. The first divided electrode PAE1 may be disposed to overlap the driving transistor DR_d1 and DR_d2 and the second divided electrode PAE2 may be disposed to overlap the first switching transistor TR1 and the second switching transistor TR2_d1 and TR2_d2.

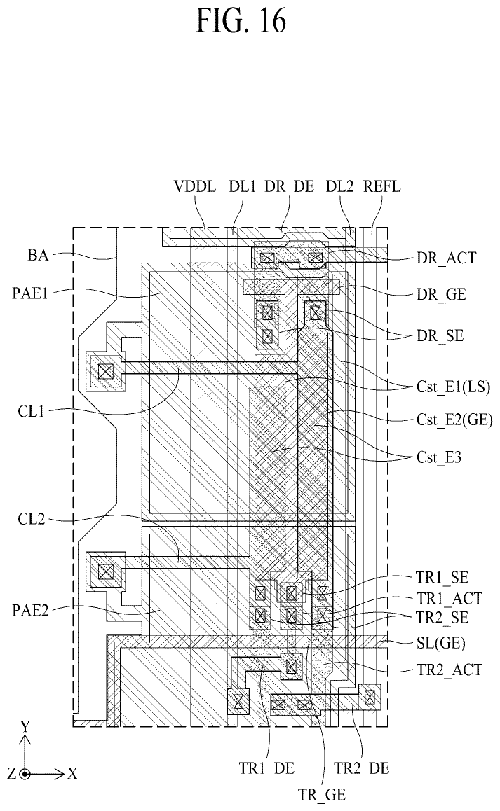

Referring to FIG. 16, a bank layer BA may be formed on the planarization layer PLN on which the first divided electrode PAE1 and the second divided electrode PAE2 are disposed. The bank layer BA covers edges of each of the first divided electrode PAE1 and the second divided electrode PAE2, and the bank layer BA may be configured to expose a portion of each of the first divided electrode PAE1 and the second divided electrode PAE2. The emission layer EL and the second electrode CE may be sequentially formed on the first divided electrode PAE1, the second divided electrode PAE2, and the bank layer BA.

A light emitting display apparatus according to one or more aspects of the present disclosure will be described below.

A light emitting display apparatus according to one or more aspects of the present disclosure may include a light emitting element including a pixel electrode, an emission layer, and a common electrode, and a pixel circuit connected to the pixel electrode of the light emitting element and configured to include at least one thin film transistor, the pixel electrode may be divided into a first pixel divided electrode and a second pixel divided electrode, and at least a portion of the at least one thin film transistor is configured as a dual transistor connected to each of the first pixel divided electrode and the second pixel divided electrode.

According to one or more aspects of the present disclosure, the dual transistor may be spaced apart from each other and disposed to face each other.

According to one or more aspects of the present disclosure, the dual transistor may be symmetrical to each other in one of a first direction and a second direction or disposed in a mirror shape.

According to one or more aspects of the present disclosure, the dual transistor may be configured to include a gate electrode in common.

According to one or more aspects of the present disclosure, the dual transistor may include a first divided transistor connected to the first pixel divided electrode, and a second divided transistor connected to the second pixel divided electrode.

According to one or more aspects of the present disclosure, the first divided transistor and the second divided transistor may be spaced apart from each other and are disposed to face each other.

According to one or more aspects of the present disclosure, the first divided transistor and the second divided transistor may be arranged to be symmetrical to each other in one of a first direction and a second direction, or may be disposed in a mirror shape.

According to one or more aspects of the present disclosure, the gate electrode of each of the first divided transistor and the second divided transistor may be connected in common.

According to one or more aspects of the present disclosure, one end of each of the first and second divided transistors may be connected to a same node, and another end of the first and second divided transistors may be connected to different nodes.

According to one or more aspects of the present disclosure, another end of the first divided transistor may be connected to the first pixel divided electrode, and another end of the second divided transistor may be connected to the second pixel divided electrode.

According to one or more aspects of the present disclosure, the first pixel divided electrode and the second pixel divided electrode may be adjacent to each other in a first direction, the pixel circuit may have a connection line extended in a second direction crossing the first direction, and the connection line may be connected to at least one of the first pixel divided electrode and the second pixel divided electrode.

According to one or more aspects of the present disclosure, one of the first pixel divided electrode and the second pixel divided electrode may be electrically separated from the connection line, and another one of the first pixel divided electrode and the second pixel divided electrode may be electrically connected to the pixel circuit through the connection line.

According to one or more aspects of the present disclosure, the pixel circuit may include a driving transistor configured to include a gate electrode connected to a first node, connected to the first pixel divided electrode and the second pixel divided electrode, and configured to generate a driving current according to a gate-to-source voltage, a first switching transistor connected between a data line to which a data voltage is applied and the first node, and a second switching transistor connected between each of the first pixel divided electrode and the second pixel divided electrode and a reference line to which a repair detection voltage is applied during a repair detection period.

According to one or more aspects of the present disclosure, the driving transistor and the second switching transistor may be formed of the dual transistor.

According to one or more aspects of the present disclosure, the first switching transistor may be formed of a single transistor.

According to one or more aspects of the present disclosure, the driving transistor may include a first driving transistor having one end connected to the first pixel divided electrode, and a second driving transistor having one end connected to the second pixel divided electrode, and another end of each of the first and second driving transistors may be commonly connected to a third node to which a pixel power voltage is applied.

According to one or more aspects of the present disclosure, the second switching transistor may include a first divided switching transistor having one end connected to the first pixel divided electrode, and a second divided switching transistor having one end connected to the second pixel divided electrode, and another end of each of the first and second divided switching transistors may be commonly connected to the reference line.

According to one or more aspects of the present disclosure, the pixel circuit may further include a storage capacitor connected between each of the first pixel divided electrode and the second pixel divided electrode and the driving transistor.

According to one or more aspects of the present disclosure, the storage capacitor may include a first storage capacitor connected to the first pixel divided electrode and a second storage capacitor connected to the second pixel divided electrode, and the first and second storage capacitors may be spaced apart from each other and arranged to face each other.

According to one or more aspects of the present disclosure, the first and second storage capacitors may be arranged to be symmetrical to each other in one of a first direction and a second direction, or may be disposed in a mirror shape.

According to one or more aspects of the present disclosure, the light emitting element may include a first divided light emitting element and a second divided light emitting element corresponding to the first pixel divided electrode and the second pixel divided electrode, respectively.

According to one or more aspects of the present disclosure, each of the first divided light emitting element and the second divided light emitting element may be independently driven by the dual transistor.

According to one or more aspects of the present disclosure, may further include a reference line electrically connected to the first divided light emitting element and the second divided light emitting element and applied with a repair detection voltage during a repair detection period, each of the first divided light emitting element and the second divided light emitting element may be driven by the repair detection voltage applied from the reference line.

According to one or more aspects of the present disclosure, whether at least one of the first divided light emitting element and the second divided light emitting element is defective may be determined based on light emitting driving of each of the first divided light emitting element and the second divided light emitting element during the repair detection period.

According to one or more aspects of the present disclosure, whether at least one of the first divided light emitting element and the second divided light emitting element is defective may be determined based on brightness by the light emitting driving of each of the first divided light emitting element and the second divided light emitting element.

A light emitting display apparatus according to one or more embodiments of the present disclosure may include a light emitting element including a pixel electrode, an emission layer, and a common electrode, and a pixel circuit connected to the pixel electrode of the light emitting element and configured to include at least one thin film transistor, the pixel electrode may be divided into a first pixel divided electrode and a second pixel divided electrode, the light emitting element may include a first divided light emitting element and a second divided light emitting element corresponding to the first pixel divided electrode and the second pixel divided electrode, respectively, and at least one thin film transistor may comprise a first driving transistor configured to drive the first divided light emitting element, and a second driving transistor configured to drive the second divided light emitting element.

According to one or more embodiments of the present disclosure, at least one thin film transistor may further comprise a first divided switching transistor connected to the first pixel divided electrode, and a second divided switching transistor connected to the second pixel divided electrode.

According to one or more embodiments of the present disclosure, the pixel circuit may include a storage capacitor comprising a first storage capacitor connected to the first pixel divided electrode and a second storage capacitor connected to the second pixel divided electrode.

It will be apparent to those skilled in the art that various modifications and variations may be made in the apparatus of the present disclosure without departing from the scope of the disclosure. Thus, it is intended that the present disclosure cover the modifications and variations of this disclosure provided that within the scope of the claims and their equivalents.

What is claimed is:

1. A light emitting display apparatus comprising:
a light emitting element including a pixel electrode, an emission layer, and a common electrode; and
a pixel circuit connected to the pixel electrode of the light emitting element and configured to include at least one thin film transistor,
wherein the pixel electrode is divided into a first pixel divided electrode and a second pixel divided electrode, and at least a portion of the at least one thin film transistor is configured as a dual transistor connected to each of the first pixel divided electrode and the second pixel divided electrode.

2. The light emitting display apparatus according to claim 1, wherein the dual transistor is spaced apart from each other and disposed to face each other.

3. The light emitting display apparatus according to claim 2, wherein the dual transistor is symmetrical to each other in one of a first direction and a second direction or is disposed in a mirror shape.

4. The light emitting display apparatus according to claim 1, wherein the dual transistor is configured to include a gate electrode in common.

5. The light emitting display apparatus according to claim 1, wherein the dual transistor includes:
a first divided transistor connected to the first pixel divided electrode; and
a second divided transistor connected to the second pixel divided electrode.

6. The light emitting display apparatus according to claim 5, wherein the first divided transistor and the second divided transistor are spaced apart from each other and are disposed to face each other.

7. The light emitting display apparatus according to claim 6, wherein the first divided transistor and the second divided transistor are arranged to be symmetrical to each other in one of a first direction and a second direction, or are disposed in a mirror shape.

8. The light emitting display apparatus according to claim 5, wherein the gate electrode of each of the first divided transistor and the second divided transistor is connected in common.

9. The light emitting display apparatus according to claim 5, wherein one end of each of the first and second divided transistors is connected to a same node, and
wherein another end of the first and second divided transistors are connected to different nodes.

10. The light emitting display apparatus according to claim 9, wherein another end of the first divided transistor is connected to the first pixel divided electrode, and
wherein another end of the second divided transistor is connected to the second pixel divided electrode.

11. The light emitting display apparatus according to claim 1, wherein the first pixel divided electrode and the second pixel divided electrode are adjacent to each other in a first direction, and
wherein the pixel circuit has a connection line extended in a second direction crossing the first direction and is connected to at least one of the first pixel divided electrode and the second pixel divided electrode.

12. The light emitting display apparatus according to claim 11, wherein one of the first pixel divided electrode and the second pixel divided electrode is electrically separated from the connection line, and
wherein another one of the first pixel divided electrode and the second pixel divided electrode is electrically connected to the pixel circuit through the connection line.

13. The light emitting display apparatus according to claim 1, wherein the pixel circuit includes:
a driving transistor configured to include a gate electrode connected to a first node, connected to the first pixel divided electrode and the second pixel divided electrode, and configured to generate a driving current according to a gate-to-source voltage;
a first switching transistor connected between a data line to which a data voltage is applied and the first node; and
a second switching transistor connected between each of the first pixel divided electrode and the second pixel divided electrode and a reference line to which a repair detection voltage is applied during a repair detection period.

14. The light emitting display apparatus according to claim 13, wherein the driving transistor and the second switching transistor are formed of the dual transistor.

15. The light emitting display apparatus according to claim 13, wherein the first switching transistor is formed of a single transistor.

16. The light emitting display apparatus according to claim 15, wherein the driving transistor includes:
a first driving transistor having one end connected to the first pixel divided electrode; and
a second driving transistor having one end connected to the second pixel divided electrode, and
wherein another end of each of the first and second driving transistors is commonly connected to a third node to which a pixel power voltage is applied.

17. The light emitting display apparatus according to claim 15, wherein the second switching transistor includes:
a first divided switching transistor having one end connected to the first pixel divided electrode; and
a second divided switching transistor having one end connected to the second pixel divided electrode, and
wherein another end of each of the first and second divided switching transistors is commonly connected to the reference line.

18. The light emitting display apparatus according to claim 13, wherein the pixel circuit further includes a storage capacitor connected between each of the first pixel divided electrode and the second pixel divided electrode and the driving transistor.

19. The light emitting display apparatus according to claim 18, wherein the storage capacitor includes a first storage capacitor connected to the first pixel divided electrode and a second storage capacitor connected to the second pixel divided electrode, and
wherein the first and second storage capacitors are spaced apart from each other and arranged to face each other.

20. The light emitting display apparatus according to claim 19, wherein the first and second storage capacitors are arranged to be symmetrical to each other in one of a first direction and a second direction, or are disposed in a mirror shape.

21. The light emitting display apparatus according to claim 1, wherein the light emitting element includes a first divided light emitting element and a second divided light emitting element corresponding to the first pixel divided electrode and the second pixel divided electrode, respectively.

22. The light emitting display apparatus according to claim 21, wherein each of the first divided light emitting element and the second divided light emitting element is independently driven by the dual transistor.

23. The light emitting display apparatus according to claim 22, further comprising a reference line electrically connected to the first divided light emitting element and the second divided light emitting element and applied with a repair detection voltage during a repair detection period,
wherein each of the first divided light emitting element and the second divided light emitting element is driven by the repair detection voltage applied from the reference line.

24. The light emitting display apparatus according to claim 23, wherein whether at least one of the first divided light emitting element and the second divided light emitting element is defective is determined based on light emitting driving of each of the first divided light emitting element and the second divided light emitting element during the repair detection period.

25. The light emitting display apparatus according to claim 24, wherein whether at least one of the first divided light emitting element and the second divided light emitting element is defective is determined based on brightness by the light emitting driving of each of the first divided light emitting element and the second divided light emitting element.

26. A light emitting display apparatus comprising:
a light emitting element including a pixel electrode, an emission layer, and a common electrode; and
a pixel circuit connected to the pixel electrode of the light emitting element and configured to include at least one thin film transistor,
wherein the pixel electrode is divided into a first pixel divided electrode and a second pixel divided electrode,
wherein the light emitting element includes a first divided light emitting element and a second divided light emitting element corresponding to the first pixel divided electrode and the second pixel divided electrode, respectively, and
wherein at least one thin film transistor comprises:
a first driving transistor configured to drive the first divided light emitting element; and
a second driving transistor configured to drive the second divided light emitting element.

27. The light emitting display apparatus according to claim 26, wherein at least one thin film transistor further comprises:
a first divided switching transistor connected to the first pixel divided electrode; and
a second divided switching transistor connected to the second pixel divided electrode.

28. The light emitting display apparatus according to claim 26, wherein the pixel circuit includes a storage capacitor comprising:
a first storage capacitor connected to the first pixel divided electrode; and
a second storage capacitor connected to the second pixel divided electrode.
